(19) United States
(12) Patent Application Publication
(10) Pub. No.: US 2026/0299431 A1
(43) Pub. Date: Oct. 1, 2026

(54) GRAPHIC DATA GENERATION METHOD, GRAPHIC DATA GENERATION DEVICE, QUANTUM BEAM WRITING METHOD, QUANTUM BEAM WRITING DEVICE, AND COMPUTER-READABLE RECORDING MEDIUM

(71) Applicant: NuFlare Technology, Inc., Yokohama-shi (JP)

(72) Inventors: Kenichi YASUI, Yokohama-shi (JP); Daisuke HARA, Yokohama-shi (JP)

(73) Assignee: NuFlare Technology, Inc., Yokohama-shi (JP)

(21) Appl. No.: 19/457,839

(22) Filed: Jan. 23, 2026

(30) Foreign Application Priority Data
Mar. 26, 2025 (JP) 2025-051996

(51) Int. Cl. G03F 7/00; G06F 30/31

(52) U.S. Cl. CPC G03F 7/704; G06F 30/31

(57) ABSTRACT

In one embodiment, a graphic data generation method includes receiving first graphic data in which a plurality of graphics are defined, and adding, in accordance with presence/absence of an adjacent graphic, adjacency information including the presence/absence of the adjacent graphic to each of the plurality of graphics to generate second graphic data to be used in a quantum beam writing device.

### CROSS REFERENCE TO RELATED APPLICATION

This application is based upon and claims benefit of priority from the Japanese Patent Application No. 2025-51996, filed on Mar. 26, 2025, the entire contents of which are incorporated herein by reference.

### FIELD

The present invention relates to a graphic data generation method, a graphic data generation device, a quantum beam writing method, a quantum beam writing device, and a computer-readable recording medium.

### BACKGROUND

With the increasing integration density of LSIs, the required circuit linewidths for semiconductor devices have been becoming finer year by year. To form desired circuit patterns on semiconductor devices, a method is employed in which a high-precision original pattern formed on a quartz substrate is reduced and transferred onto a wafer using a reduction-projection exposure apparatus. For the fabrication of such high-precision original patterns, so-called electron-beam lithography technology is used, in which an electron-beam writing apparatus exposes a resist to form patterns.

A writing device performs edge processing such as edge emphasis processing for improving resolution and reducing edge-position error, and bias correction processing for preliminarily correcting excess/deficiency of line width caused by pattern density or process conditions in a writing pattern.

At a stage of generating, from design data, the graphic data to be input to the writing device, one pattern may be divided into a plurality of graphics. When edge processing is performed in the writing device, it is necessary to determine whether an edge defined in the input graphic data lies on an internal division line of the pattern or not.

For example, in the design data, one pattern P0 as shown in FIG. 10A may be divided into two graphics F1 and F2 as shown in FIG. 10B at the stage of generating graphic data to be input to the writing device. When negative bias processing for narrowing the line width of a pattern is performed on the pattern P0, ideally, a pattern P1 as shown in FIG. 10C is obtained. However, when negative bias processing is performed on the graphics F1 and F2 without recognizing that the right edge h of the graphic F1 is an edge lying inside the pattern P0, two separated patterns P2 and P3 as shown in FIG. 10D will be generated, so that writing accuracy is degraded.

In a writing device according to the related art, a process for expanding (flattening) the input graphic data and searching for adjacent graphics is performed. However, when a large number of graphics exist in the graphic data, the processing time becomes long, and it becomes difficult to perform the processing within the writing device.

### BRIEF DESCRIPTION OF THE DRAWINGS

FIG. 1 is a schematic diagram of a writing device according to an embodiment of the present invention.

FIG. 2 is a diagram for explaining an example of edge processing.

FIG. 3 is a diagram for explaining an example of bias processing when there is an adjacent graphic.

FIG. 4 is a diagram for explaining an example of edge emphasis processing when there is an adjacent graphic.

FIG. 5 is a diagram showing an example of adding adjacency information.

FIG. 6 is a diagram showing an example of adding adjacency information

FIG. 7 is a diagram showing an example of adding adjacency information.

FIG. 8 is a diagram showing an example of adding adjacency information.

FIG. 9 is a diagram showing an example of adding adjacency information.

FIGS. 10A and 10B are diagrams showing an example of dividing a graphic, FIG. 10C is a diagram showing an example of the bias processing, and

FIG. 10D is a diagram showing an example of performing the bias processing without considering adjacent graphics.

FIG. 11A is a diagram illustrating an example of graphic division, and

FIG. 11B is a diagram illustrating an example of bias processing.

FIG. 12A is a diagram illustrating an example of adjacent graphics, FIG. 12B is a diagram illustrating an example of bias processing, and FIG. 12C is a diagram illustrating a method for determining adjacent graphics.

FIG. 13A is a diagram illustrating an example of adjacent graphics, FIG. 13B is a diagram illustrating an example of bias processing, and FIG. 13C is a diagram illustrating a method for determining adjacent graphics.

FIGS. 14A to 14D are diagrams showing examples of setting a first partition region.

### DETAILED DESCRIPTION

In one embodiment, a graphic data generation method includes receiving first graphic data in which a plurality of graphics are defined, and adding, in accordance with presence/absence of an adjacent graphic, adjacency information including the presence/absence of the adjacent graphic to each of the plurality of graphics to generate second graphic data to be used in a quantum beam writing device.

The embodiments of the present invention will now be described below with reference to the drawings. In the embodiments, a configuration using an electron beam is described as one example of a quantum beam. However, the quantum beam is not limited to an electron beam, and may instead be a charged particle beam such as an ion beam, or a laser.

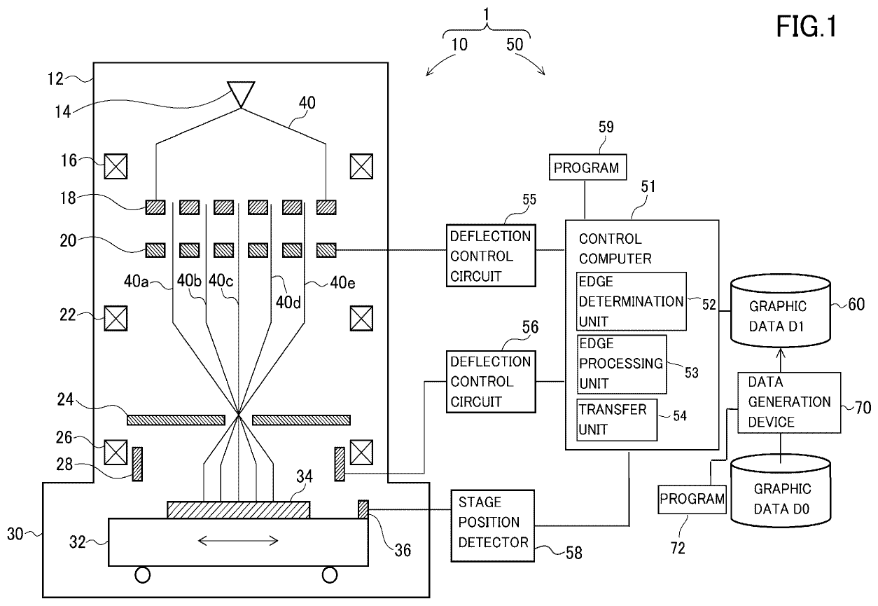

FIG. 1 is a schematic diagram of a multiple charged particle beam writing device 1 (hereinafter referred to as writing device 1) according to the present embodiment that writes a pattern using graphic data. The writing device 1 includes a writing unit 10 that irradiates a substrate 34, which is a target to be written such as a mask blank or a wafer, with an electron beam to write a desired pattern, and a control unit 50 that controls a writing operation performed by the writing unit 10. The writing unit 10 has an electron optical lens-barrel 12 and a writing chamber 30.

An electron source 14, an illumination lens 16, a shaping aperture array substrate 18, a blanking aperture array substrate 20, a reduction lens 22, a limiting aperture member 24, an objective lens 26, and a deflector 28 are disposed in the electron optical lens-barrel 12. An XY stage 32 is disposed in the writing chamber 30. The substrate 34, which is a target to be written, is placed on the XY stage 32. Further, a mirror 36 for measuring the position of the XY stage 32 is disposed on the XY stage 32.

The control unit 50 includes a control computer 51, deflection control circuits 55 and 56, and a stage position detector 58. The control computer 51, the deflection control circuits 55 and 56, and the stage position detector 58 are connected to each other via a bus.

An electron beam 40 emitted from the electron source 14 illuminates the shaping aperture array substrate 18 substantially vertically by the illumination lens 16. In the shaping aperture array substrate 18, a plurality of apertures are formed in a matrix shape with a predetermined arrangement pitch. The electron beam 40 illuminates a region of the shaping aperture array substrate 18 including the plurality (all) of apertures. When a part of the electron beam 40 passes through the plurality of apertures, multi-beams 40a to 40e as shown in FIG. 1 are formed.

In the blanking aperture array substrate 20, passing holes are formed corresponding to the arrangement positions of the apertures of the shaping aperture array substrate 18, and a blanker consisting of two electrodes as a pair is arranged in each passing hole. The multi-beams 40a to 40e passing through the passing holes are each independently deflected by a voltage applied by the blanker, so that blanking thereof is controlled. In such a manner, the plurality of blankers perform blanking deflection on, among the multi-beams which have passed through the plurality of apertures of the shaping aperture array substrate 18, the respective corresponding individual beams. The blankers deflect the individual beams based on a blanking control signal from the deflection control circuit 55.

The multi-beams 40a to 40e which have passed through the blanking aperture array substrate 20 are reduced by the reduction lens 22, and advance toward an aperture formed in the limiting aperture member 24. Here, the individual beams deflected by the blankers of the blanking aperture array substrate 20 deviate from the aperture of the limiting aperture member 24, and are stopped by the limiting aperture member 24 as a shield. On the other hand, the individual beams which have not been deflected by the blankers of the blanking aperture array substrate 20 pass through the aperture of the limiting aperture member 24.

Thus, the limiting aperture member 24 as a shield stops the respective beams which have been deflected by the blankers of the blanking aperture array substrate 20 so that the beams are turned OFF. The beams which have passed through the limiting aperture member 24 from the time when the beams are turned ON to the time when the beams are turned OFF become the beams of one shot. The multi-beams 40a to 40e which have passed through the limiting aperture member 24 are each focused by the objective lens 26 to form a pattern image at a desired reduction ratio. The respective beams (the entire multi-beams) which have passed through the limiting aperture member 24 are collectively deflected in the same direction by the deflector 28, and the substrate 34 is irradiated with the deflected beams. The deflector 28 operates based on a control signal from the deflection control circuit 56.

When the XY stage 32 is continuously moving, the irradiation position of the beams is controlled by the deflector 28 so as to follow the movement of the XY stage 32. The movement of the XY stage 32 is performed by a stage controller (not shown). The stage position detector 58 has a laser interferometer for irradiating the mirror 36 with a laser and receiving the reflected light, detects the position of the XY stage 32, and notifies the stage controller of the position of the XY stage 32.

Ideally, the multi-beams irradiated at one time are arranged at a pitch obtained by multiplying the arrangement pitch of the plurality of apertures of the shaping aperture array substrate 18 by the desired reduction ratio described above. The writing device 1 performs a writing operation by a raster scan method in which shot beams are continuously and sequentially irradiated, and when writing a desired pattern, necessary beams according to the pattern are controlled to be turned ON by blanking control.

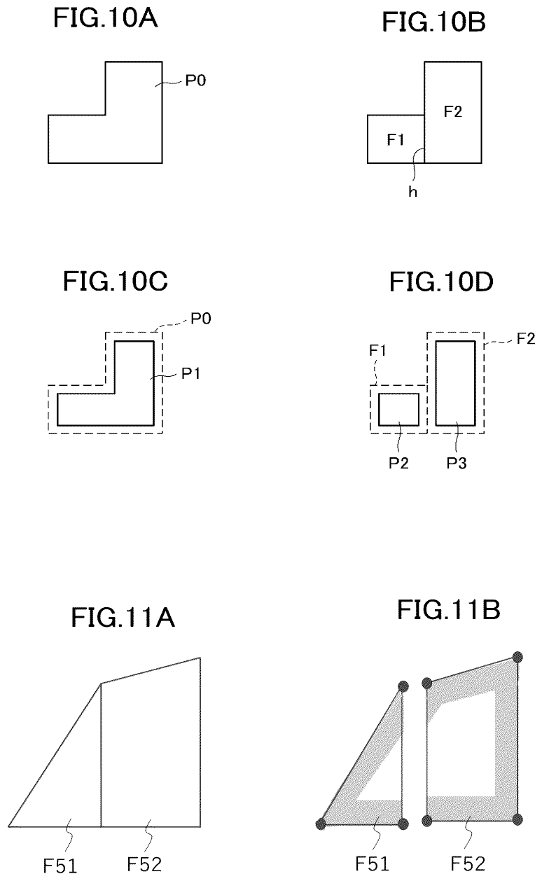

The control computer 51 has an edge determination unit 52, an edge processing unit 53, and a transfer unit 54. The edge determination unit 52 reads graphic data D1 (second graphic data) from a storage device 60, and determines whether or not the edge of the graphic defined in the graphic data D1 is inside a line that divides one pattern, i.e., whether or not the edge of the graphic defined in the graphic data D1 is inside such a pattern. For example, when the edge of the graphic defined in the graphic data D1 is an edge of the graphic F1 such as the side h shown in FIG. 10B, there is the adjacent graphic F2, and the edge is an edge composed of the graphics F1 and F2, the edge determination unit 52 determines whether or not the edge is located inside one pattern P0. The structure of the graphic data D1 and an edge determination method will be described later.

The edge processing unit 53 performs edge processing using the determination result of the edge determination unit 52. The edge processing includes bias processing and edge emphasis processing, in which the bias processing increases or decreases the line width of the pattern, and the edge emphasis processing increases the radiation dose at the edge portion more than the radiation dose at the region inside the edge portion.

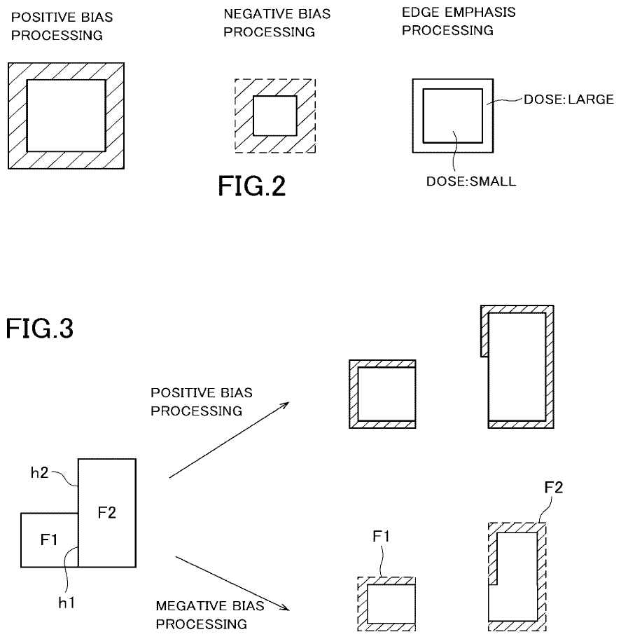

For example, the edge processing unit 53 performs, as shown in FIG. 2, positive bias processing for increasing the line width of a pattern, or negative bias processing for decreasing the line width of the pattern. In the positive bias processing, a region indicated by hatched lines is added to the outside of the graphic. In the negative bias processing, a region indicated by hatched lines is removed from the graphic. The bias amount, which is the width of the hatched region, may be, for example, a value inputted and set to the control computer 51 or a value held in the control computer 51.

In the edge emphasis processing, for example, the radiation dose of the edge peripheral portion (for example, a belt-like region having a width inside the edge position) of the graphic is increased, and the radiation dose of the region inside the edge peripheral portion is decreased. Note that the radiation dose of the region inside the edge portion need not necessarily be decreased.

When there are adjacent graphics, the bias processing is performed in consideration of the adjacent graphics. For example, as shown in FIG. 3, the bias processing is performed in consideration of the determination result of the edge determination unit 52 that the graphic F2 is adjacent to the graphic F1, and that the right side h1 of the graphic F1 and a portion (lower portion) of the left-side h2 of the graphic F2 are located inside one pattern. In the positive bias processing, regions indicated by hatched lines are added outside the graphics F1 and F2. In the negative bias processing, regions indicated by hatched lines are removed from the graphics F1 and F2.

The edge processing unit 53 performs rasterization processing to virtually divide the writing region of the substrate 34 into a plurality of pixels with a predetermined size (for example, the size of one beam of the multi-beams) and calculate the area density ρ of graphic patterns arranged in each pixel. The edge processing unit 53 calculates the area density ρ of the graphics arranged for each pixel after bias processing, and calculates a radiation dose by multiplying the calculated area density ρ by a preset reference radiation dose D.

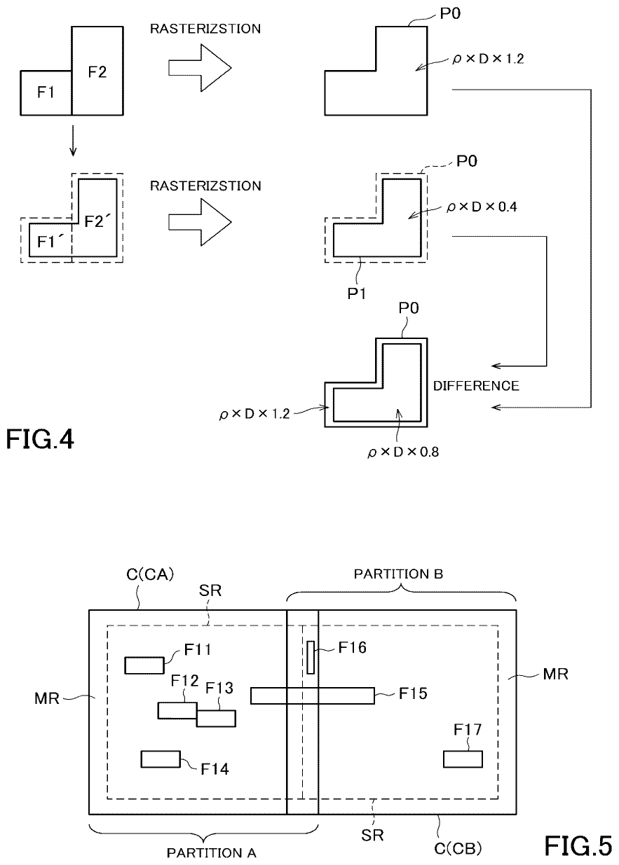

FIG. 4 shows an example of edge emphasis processing in which adjacent graphics are considered. In the edge emphasis processing, the same processing as the negative bias processing is performed to generate graphics F1′ and F2′ from which the edge regions of the graphics F1 and F2 are removed. The edge processing unit 53 performs the rasterization processing on the graphics F1 and F2 and the graphics F1′ and F2′, and obtains a radiation dose for each pixel by multiplying the graphics F1 and F2 and the graphics F1′ and F2′ by different coefficients.

For example, the edge processing unit 53 calculates an area density ρ of the graphics F1 and F2 arranged for each pixel, and calculates a radiation dose by multiplying the calculated area density ρ by the reference radiation dose D and a predetermined first coefficient (for example, 1.2) larger than 1. As a result, a radiation dose of ρ×D×1.2 is calculated for a pixel in which a pattern P0 composed of the graphics F1 and F2 is arranged.

Further, the edge processing unit 53 calculates an area density ρ of the graphics F1′ and F2′ arranged for each pixel, and calculates a radiation dose by multiplying the area density ρ by the reference radiation dose D and a second coefficient (for example, 0.4) smaller than the first coefficient. As a result, a radiation dose of ρ×D×0.4 is calculated for a pixel in which a pattern P1 composed of the graphics F1′ and F2′, in other words, a pattern P1 inside the pattern P0 obtained by excluding an edge portion (a belt-like region having a predetermined width inside the edge position of the pattern P0) from the pattern P0, is arranged.

By subtracting the radiation dose ρ×D×0.4 of the pixel in which the pattern P1 is arranged from the radiation dose ρ×D×1.2 of the pixel in which the pattern P0 is arranged, a radiation dose of ρ×D×1.2 is obtained for the edge portion of the pattern P0, and a radiation dose of ρ×D×0.8 is obtained for the region located inside the edge position and obtained by excluding the edge portion from the pattern P0.

In such a manner, the edge emphasis processing in which the radiation dose of the edge portion is increased can be performed.

The transfer unit 54 calculates the irradiation time by dividing the radiation dose of each pixel by the current density, rearranges the calculated irradiation time data of each pixel in the order of shots, and transfers the data to the deflection control circuit 55. The deflection control circuit 55 transmits a blanking control signal based on the calculated irradiation time to the blanking aperture array substrate 20.

In the present embodiment, the edge determination unit 52 is a unit for generating the graphic data D1 for efficiently performing edge determination.

A method of generating the graphic data D1 will be described. When a layout of a semiconductor integrated circuit is designed, design data (CAD data, graphic data) serving as layout data is generated, and graphic data D0 (first graphic data) to be inputted to a writing device is generated from the design data. Information such as the position (vertex coordinates), shape, and size of each graphic is defined in the graphic data D0. At the stage of generating the graphic data D0, one pattern may be divided into a plurality of graphics. Also, at the stage of design data, one pattern may be divided into a plurality of graphics. Note that D0 may be design data, and D1 may be data to be inputted to a writing device.

A data generation device 70 generates the graphic data D1 by adding adjacency information including presence/absence of an adjacent graphic to each graphic defined in the graphic data D0. The graphic data D1 is stored in the storage device 60.

When the graphic data D0 to be inputted to a writing device is generated from the design data, if one graphic is divided into a plurality of graphics, since an adjacent graphic always exists in the divided graphics, adjacency information may be added to the divided graphics by using information that one graphic has been divided.

Further, it is also possible to analyze the graphic data D0, without using information that the graphic has been divided, detect an adjacent graphic, and add adjacency information including presence/absence of the adjacent graphic to each graphic.

An adjacency information adding function of the data generation device 70 may be configured by hardware or software. When the adjacency information adding function is configured by software, a program for realizing the function may be stored in a recording medium 72, and the program may be read and executed by a computer. The recording medium 72 is not limited to a fixed type device such as a hard disk device or a memory, but may be a removable type device such as a magnetic disk or an optical disk.

As shown in FIG. 5, the data generation device 70 sets rectangular first partition regions C arranged in the x direction (first direction) and the y direction (second direction orthogonal to the first direction), and adds adjacency information to graphics in each region in units of first partition regions. The size and shape of the first partition region C are not particularly limited; for example, the first partition region C may have a square shape with a side length of 128 μm.

A frame-shaped margin region MR is set in a peripheral portion in each first partition region C. The width of the margin region MR is not particularly limited, but may be, for example, about 100 nm. The region inside the margin region MR is defined as a second partition region SR.

The first partition regions C are set so that portions of the first partition regions C adjacent to each other overlap with each other. Specifically, in the first partition regions C adjacent to each other, the second partition regions SR are in contact with each other such that they share one side, and the margin region MR overlaps with the second partition region SR of the adjacent first partition region C. In the example shown in FIG. 5, the second partition region SR in a first partition region CA of a partition A is in contact with the second partition region SR in a first partition region CB of a partition B. Further, the margin region MR in the first partition region CA of the partition A overlaps with the second partition region SR in the first partition region CB of the partition B. The margin region MR in the first partition region CB of the partition B overlaps with the second partition region SR in the first partition region CA of the partition A.

The data generation device 70 adds a 2-bit adjacent flag (b2, b1), as adjacency information, to each graphic defined in the graphic data D0. The value b1 of the first bit of the flag indicates presence/absence of an adjacent graphic. The value b2 of the second bit of the flag indicates whether the graphic is located in the second partition region SR, or located in the margin region MR. For example, the adjacent flag has the following contents.

(b2, b1)=
0,0: no adjacency (second partition region)
0,1: have adjacency (second partition region)
1,0: no adjacency (margin region)
1,1: have adjacency (margin region)

In the example shown in FIG. 5, the adjacent flag (0,0) is added to graphics F11, F14, and F17. The adjacent flag (0,1) is added to graphics F12 and F13.

In the case of a graphic that extends over first partition regions adjacent to each other, such as a graphic F15, the graphic is divided into a plurality of graphics at the boundary of the respective first partition regions, and the plurality of graphics are defined in the respective first partition regions. In the portion where the first partition regions overlap with each other, the graphic is doubly defined in the overlapped first partition regions. The graphic is also divided at the boundary between the second partition region SR and the margin region MR.

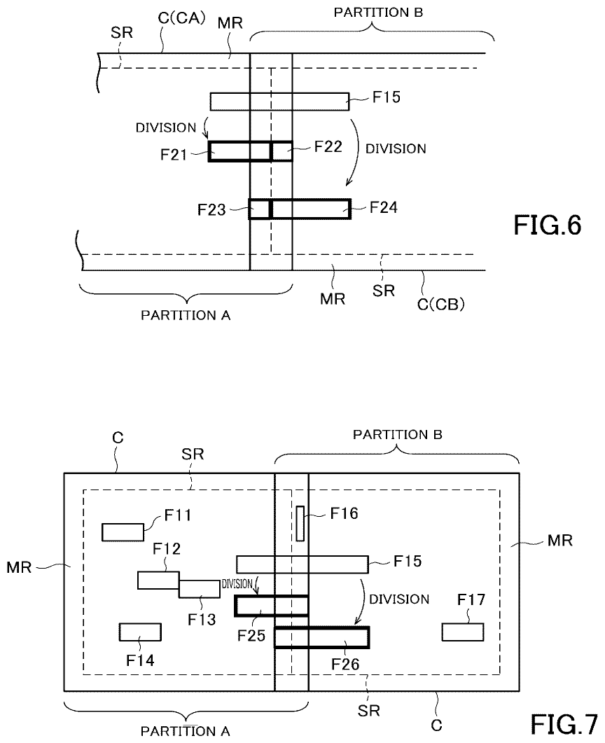

For example, as shown in FIG. 6, the graphic F15 is divided at the boundary of the first partition region CA, and further divided at the boundary between the second partition region SR and the margin region MR in the first partition region CA, so that graphics F21 and F22 are defined in the first partition region CA (in which a graphic having a shape close to a square in FIG. 6 is the graphic F22). Further, the graphic F15 is divided at the boundary of the first partition region CB, and further divided at the boundary between the second partition region SR and the margin region MR in the first partition region CB, so that graphics F23 and F24 are defined in the first partition region CB (in which a graphic having a shape close to a square in FIG. 6 is the graphic F23). The graphics are doubly defined in regions where the first partition region CA and the first partition region CB overlap with each other. In this example, the graphic F22 and the graphic F23 are doubly defined in the first partition region CA and the first partition region CB.

The adjacent flag (0,1) is added to the graphics F21 and F24. The adjacent flag (1,1) is added to the graphics F22 and F23.

A graphic F16 is doubly defined, and the adjacent flag (1,0) is added to the graphic F16 in the first partition region CA, and the adjacent flag (0,0) is added to the graphic F16 in the first partition region CB.

The data generation device 70 adds such an adjacent flag (adjacency information) to each graphic defined in the graphic data D0 to generate the graphic data D1.

The edge determination unit 52 reads the graphic data D1 from the storage device 60, and performs edge determination in units of first partition regions. The edge determination unit 52 determines that a graphic to which an adjacent flag having a value b1 of the first bit of 0 is added has no adjacent graphic and has no edge located inside the pattern. The edge processing unit 53 performs the edge processing for such a graphic without considering the adjacent graphic.

The edge determination unit 52 determines that a graphic to which an adjacent flag whose first bit b1 is 1 is added has an adjacent graphic and that there exists an edge located inside the pattern. The edge determination unit 52 identifies the adjacent graphic from the positions and sizes of other graphics whose value b1 of the first bit of the adjacent flag in the first partition region is 1. For example, the edge determination unit 52 identifies that the graphics F21 and F22 are adjacent graphics from the positions and sizes of other graphics in the first partition region of the graphics F21 and F22 to which an adjacent flag having a value b1 of the first bit of 1 is added.

Therefore, the adjacent graphic can be efficiently identified without checking all graphics in the first partition region. The edge processing unit 53 performs the edge processing in consideration of the adjacent graphic (see FIGS. 3 and 4).

After performing the edge processing, the edge processing unit 53 discards the graphics in which the value b2 of the second bit is 1, that is, the graphics in the margin region MR. This is because graphics in the margin region MR are also defined in the second partition region of another first partition region.

In such a manner, by adding an adjacent flag to each graphic, the edge processing can be efficiently performed in units of first partition regions without expanding the entire graphic data D1, so that the processing time can be reduced. Further, in the search processing for the adjacent graphic to be considered, since only graphics in which the value b1 of the first bit of the adjacent flag is 1 need to be targeted, and since such graphics usually exist only at the boundary of the partition regions, the number of graphics is small, so that the search processing can be efficiently performed.

In the above embodiment, an example of adding an adjacent flag of 2 bits has been described, but an adjacent flag of 1 bit indicating presence/absence of an adjacent graphic may be added. For example, the value of the adjacent flag of 1 bit being 0 indicates that there is no adjacent graphic, and the value of the adjacent flag of 1 bit being 1 indicates that there is an adjacent graphic.

In the example shown in FIG. 7, the adjacent flag (0) is added to the graphics F11, F14, F16, and F17. The adjacent flag (1) is added to the graphics F12 and F13.

In the case of a graphic that extends over first partition regions adjacent to each other, such as the graphic F15, the graphic is divided at the boundary of the respective first partition regions. In the portion where the first partition regions overlap with each other, the graphic is doubly defined. The graphic F15 is divided at the boundary of the first partition region CA, so that a graphic F25 is defined in the first partition region CA. Further, the graphic F15 is divided at the boundary of the first partition region CB, so that a graphic F26 is defined in the first partition region CB. The adjacent flag (1) is added to the graphics F25 and F26.

The data generation device 70 adds a 1-bit adjacent flag (adjacency information) to each graphic to generate the graphic data D1.

The edge determination unit 52 reads the graphic data D1 from the storage device 60, and performs edge determination in units of first partition regions. The edge determination unit 52 determines that a graphic whose adjacent flag value is 0 has no adjacent graphic, and has no edge located inside the pattern. The edge processing unit 53 performs the edge processing for such a graphic without considering the adjacent graphic.

The edge determination unit 52 determines that a graphic whose adjacent flag value is 1 has an adjacent graphic, and has an edge located inside the pattern. The edge determination unit 52 identifies the adjacent graphic from the positions and sizes of other graphics whose adjacent flag value is 1 in the first partition region. Therefore, the adjacent graphic can be efficiently identified without checking all graphics in the first partition region. The edge processing unit 53 performs the edge processing in consideration of the adjacent graphic (see FIGS. 3 and 4).

After performing the edge processing, the edge processing unit 53 discards the graphics in the margin region MR.

In such a manner, even by adding a 1-bit adjacent flag to each graphic, the edge processing can be efficiently performed in units of first partition regions without expanding the entire graphic data D1, so that the processing time can be reduced.

It is also possible to add an adjacent flag indicating presence/absence of an adjacent graphic to each graphic without setting the first partition region, and add, if there is an adjacent graphic, adjacent graphic information. The adjacent graphic information is information defining at least a portion of the adjacent graphic, and is, for example, vertex information of the adjacent graphic.

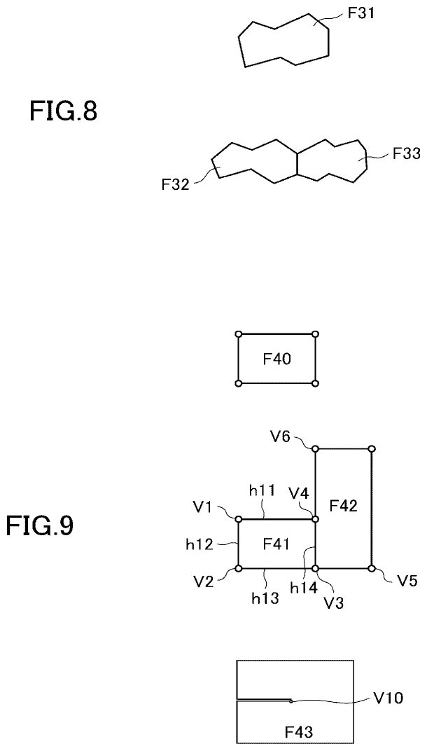

Since a graphic F31 shown in FIG. 8 has no adjacent graphic, an adjacent flag having a value of 0 is added to the graphic F31.

Since a graphic F32 has an adjacent graphic, an adjacent flag having a value of 1 is added to the graphic F32, and adjacent graphic information including vertex information of an adjacent graphic F33 is added to the graphic F32. Since the graphic F33 has an adjacent graphic, an adjacent flag having a value of 1 is added to the graphic F33, and adjacent graphic information including vertex information of the adjacent graphic F32 is added to the graphic F33.

The data generation device 70 generates the graphic data D1 by adding the adjacent flag and the adjacent graphic information.

The edge determination unit 52 reads the graphic data D1 from the storage device 60, and determines that the graphic whose value of the adjacent flag is 0 has no adjacent graphic and has no edge located inside the pattern. The edge processing unit 53 performs the edge processing for such a graphic without considering the adjacent graphic.

For the graphic whose value of the adjacent flag is 1, the edge determination unit 52 detects an edge in contact with the adjacent graphic by using the adjacent graphic information. The edge processing unit 53 performs the edge processing by considering the adjacent graphic.

In such a manner, by adding a 1-bit adjacent flag to each graphic, and adding, if there is an adjacent graphic, adjacent graphic information, the edge processing can be efficiently performed without expanding the entire graphic data D1.

As the adjacency information, attribute information for identifying whether or not each vertex of the graphic is located on a side of the adjacent graphic may be further added. In a polygon, a vertex is a point where two sides (edges) intersect. When two edges are external edges, a vertex where the two edges intersect is defined as an external point. When two edges are internal edges, a vertex where the two edges intersect is defined as an internal point. A vertex where an external edge and an internal edge intersect is defined as a joint point. Further, among the vertices of the adjacent graphic, a vertex adjacent to a joint point is defined as an adjacent auxiliary point.

For example, adjacency information including attribute information indicating that all four sides are external edges and four vertices are external points is added to a graphic F40 shown in FIG. 9.

A graphic F41 and a graphic F42 are adjacent to each other. Sides h11 to h13 of the graphic F41 are external edges, and a side h14 is an internal edge. Therefore, vertices V1 and V2 are external points, and vertices V3 and V4 are joint points. A vertex V5 of the graphic F42 is an adjacent auxiliary point of the vertex V3. A vertex V6 of the graphic F42 is an adjacent auxiliary point of the vertex V4.

Attribute information indicating that the vertices V1 and V2 are external points, and the vertices V3 and V4 are joint points, and adjacency information including the coordinates of the vertex V5, which is the adjacent auxiliary point of the vertex V3, and the coordinates of the vertex V6, which is the adjacent auxiliary point of the vertex V4, are added to the graphic F41. A plurality of adjacent auxiliary points may be designated.

A vertex such as a vertex V10 of a graphic F43 is an internal point.

The data generation device 70 generates the graphic data D1 by adding adjacency information including such attribute information to each graphic defined in the graphic data D0.

The edge determination unit 52 reads the graphic data D1 from the storage device 60 and determines whether each edge is an external edge or an internal edge from the attribute information of each vertex. The edge determination unit 52 determines an edge whose both ends are external points as an external edge. The edge determination unit 52 determines an edge whose one end is an external point and whose other end is a joint point as an external edge. The edge determination unit 52 determines an edge whose both ends are joint points or internal points as an internal edge.

The edge processing unit 53 performs the edge processing with respect to an external edge whose both ends are external points without considering the adjacent graphic. The edge processing unit 53 performs the edge processing with respect to an internal edge and an external edge whose one end is a joint point in consideration of the coordinates of the adjacent auxiliary point.

Thus, by adding adjacency information including attribute information of each vertex and the coordinates of adjacent auxiliary points, the edge processing can be efficiently performed without expanding the entire graphic data D1.

The graphic defined in the graphic data D0 is not limited to a rectangle graphic, but may be a polygon graphic and a graphic in which straight lines and curves (including parametric curves) coexist.

A case where one pattern is divided into two graphics F51 and F52 which are polygons having any angles as shown in FIG. 11A is considered. The gray portions in FIG. 11B show ideal negative bias processing performed on the graphics F51 and F52. In order to perform such bias processing, angle information of the sides of the adjacent graphic, i.e., vertex coordinates of the adjacent graphic, is required. In each of the above embodiments, by adding vertex information of the adjacent graphic to the polygon defined in the graphic data D0 to generate the graphic data D1, the edge processing unit 53 can perform the edge processing with high accuracy.

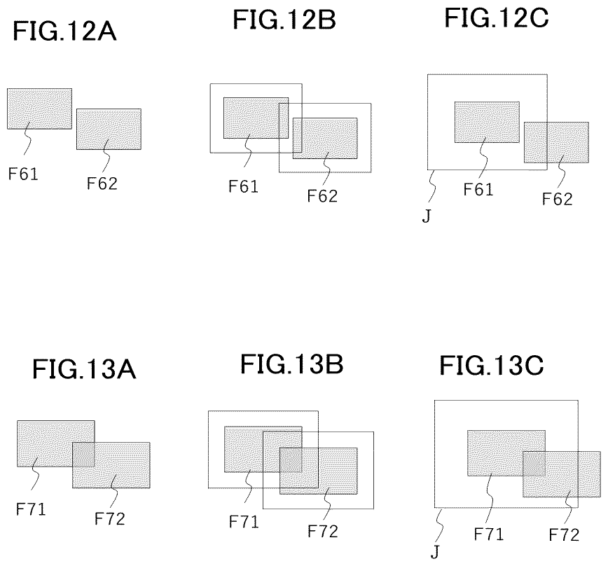

In each of the embodiments corresponding to FIGS. 5 to 8, the adjacent graphic is not limited to graphics sharing one side, but may be graphics F61 and F62 slightly separated from each other as shown in FIG. 12A, or graphics F71 and F72 partially overlapped as shown in FIG. 13A.

When the positive bias processing is performed on the graphics F61 and F62, since overlapping of the graphics occurs as shown in FIG. 12B, and it is necessary to know the adjacent graphic (proximal graphic). A range in which presence/absence of an adjacent graphic is judged from the edge of each graphic is set, and the graphics in such a range are regarded as the adjacent graphic.

For example, as shown in FIG. 12C, a range J is set based on the edge of the graphic F61. The graphic F62 in such a range J is judged as an adjacent graphic of the graphic F61. The range J is determined based on a maximum distance at which influences may be exerted during the bias processing, and such a distance may be, for example, a distance two times the maximum value of the bias amount. Further, the range J may be determined based on a maximum influence distance at which influences may be exerted during other processing (correction processing) in which consideration of the influence of nearby edges or graphics, instead of being limited to the influence of the bias amount, are required. Such a distance for determining the adjacent graphic may be provided from outside the writing device, or may be generated inside the writing device.

FIG. 13B shows a case where the positive bias processing is performed on the graphics F71 and F72. As shown in FIG. 13C, the range J is set based on the edges of the graphic F71. The graphic F72 in the range J is determined to be an adjacent graphic of the graphic F71.

In the example shown in FIG. 5, a plurality of first partition regions C are arranged at regular intervals along the x and y directions; that is, the first partition regions C adjacent to each other in the x direction have the same y position, and the first partition regions C adjacent to each other in the y direction have the same x position. However, the size and arrangement of the first partition regions C are not limited as long as the first partition region C overlaps the surrounding first partition regions C by a margin.

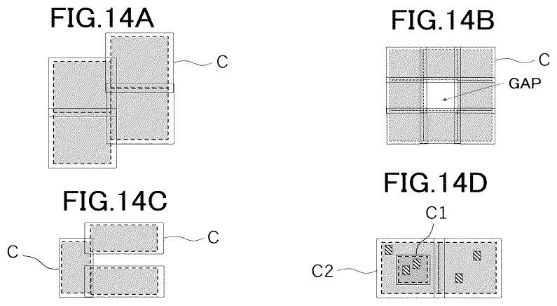

For example, as shown in FIG. 14A, the y positions of the first partition regions C adjacent to each other in the x direction may be shifted. In FIG. 14A, gray portions surrounded by broken lines indicates the second partition regions obtained by excluding the margin regions.

As shown in FIG. 14B, there may be a gap first partition region C.

As shown in FIG. 14C, the sizes (shapes) of the first partition regions C may be different from each other.

As shown in FIG. 14D, the whole of a first partition region C1 including only graphics having no adjacent graphic may overlap with another first partition region C2.

In the above embodiment, a multi-beam irradiation apparatus that irradiates a large number of beams at once using a multi-beam has been described. However, the same approach can also be applied to a single-beam irradiation apparatus that irradiates the target substrate with a single beam.

At least a portion of the control computer 51 may be implemented in hardware or in software. When implemented in software, a program for realizing at least part of the functions of the control computer 51 may be stored in a recording medium 59, loaded into a computer, and executed. The recording medium 59 is not limited to fixed media such as a hard disk device or memory, and may be a removable medium such as a magnetic disk or an optical disk.

Furthermore, a program for realizing at least part of the functions of the data generation device 70 or the control computer 51 may be distributed via communication lines such as the Internet (including wireless communication). In addition, the program may be distributed in an encrypted, modulated, or compressed form via wired or wireless communication lines such as the Internet, or stored in a recording medium for distribution.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A graphic data generation method comprising:
receiving first graphic data in which a plurality of graphics are defined; and
adding, in accordance with presence/absence of an adjacent graphic, adjacency information including the presence/absence of the adjacent graphic to each of the plurality of graphics to generate second graphic data to be used in a quantum beam writing device.

2. The graphic data generation method according to claim 1, further comprising:
setting a plurality of first partition regions so that portions of first partition regions adjacent to each other overlap with each other, and that each first partition region includes a second partition region and a margin region outside the second partition region; and
dividing a graphic that extends over first partition regions adjacent to each other into graphics at a boundary of the first partition regions, and adding the adjacency information to the graphics after division.

3. The graphic data generation method according to claim 2, further comprising:
dividing a graphic that extends over the second partition region and the margin region of one first partition region at a boundary between the second partition region and the margin region; and
adding the adjacency information to graphics after division, the adjacency information indicating presence/absence of an adjacent graphic and whether the adjacent graphic is located in the second partition region or the margin region.

4. The graphic data generation method according to claim 1, wherein the adjacency information further includes vertex information of the adjacent graphic.

5. The graphic data generation method according to claim 1, wherein the adjacency information further includes information indicating whether each vertex of the graphic is an external point where external edges intersect, a joint point where an external edge and an internal edge intersect, or an internal point where internal edges intersect, and coordinates of an adjacent auxiliary point which is a vertex adjacent to the joint point among the vertices of the adjacent graphic.

6. A graphic data generation device configured to:
receive first graphic data in which a plurality of graphics are defined; and
add, in accordance with presence/absence of an adjacent graphic, adjacency information including the presence/absence of the adjacent graphic to each of the plurality of graphics to generate second graphic data to be used in a quantum beam writing device.

7. A non-transitory computer-readable recording medium storing a program for causing a computer to execute the steps of:
receiving first graphic data in which a plurality of graphics are defined; and
adding, in accordance with presence/absence of an adjacent graphic, adjacency information including the presence/absence of the adjacent graphic to each of the plurality of graphics to generate second graphic data to be used in a quantum beam writing device.

8. A quantum beam writing method comprising:
reading, from a storage device, graphic data obtained by adding adjacency information including presence/absence of an adjacent graphic to a graphic to be written;
identifying the adjacent graphic based on the adjacency information;
performing edge processing of each graphic in consideration of the adjacent graphic;
virtually dividing a writing region of a writing target substrate into a plurality of pixels with a predetermined size, and calculating an area density of a graphic arranged in each pixel after the edge processing;
calculating a radiation dose of a quantum beam using the area density; and
irradiating the writing target substrate with the quantum beam at the radiation dose to write a graphic pattern.

9. The quantum beam writing method according to claim 8, wherein
a second graphic is generated in the edge processing by excluding an edge portion of a first graphic, and
the radiation dose is calculated so that a radiation dose at the edge portion is larger than a radiation dose at the second graphic.

10. A quantum beam writing device comprising:
an edge determination unit that reads, from a storage device, graphic data obtained by adding adjacency information including presence/absence of an adjacent graphic to a graphic to be written, and identifies the adjacent graphic based on the adjacency information;
an edge processing unit that performs edge processing of each graphic in consideration of the adjacent graphic, virtually divides a writing region of a writing target substrate into a plurality of pixels with a predetermined size, and calculates an area density of a graphic arranged in each pixel after the edge processing; and
a writing unit that irradiates the writing target substrate with a quantum beam at a quantum beam radiation dose calculated using the area density to write a graphic pattern.
